(19) United States
(12) Patent Application Publication
(10) Pub. No.: US 2024/0379375 A1
(43) Pub. Date: Nov. 14, 2024

(54) METHOD AND APPARATUS FOR ETCHING A CARBON CONTAINING LAYER

(71) Applicant: Lam Research Corporation, Fremont, CA (US)

(72) Inventors: Xiaofeng SU, Fremont, CA (US); Priyadarsini SUBRAMANIAN, Milpitas, CA (US); Zhongkui TAN, Fremont, CA (US); Yoshie KIMURA, Castro Valley, CA (US); Haoquan YAN, Fremont, CA (US); Denis Andreievich SYOMIN, Scotts Valley, CA (US); Jing LI, Milpitas, CA (US); Yijun CHEN, Newark, CA (US)

(21) Appl. No.: 18/683,501

(22) PCT Filed: Sep. 1, 2022
(86) PCT No.: PCT/US2022/042369

§ 371 Date: Feb. 13, 2024

Related U.S. Application Data
(60) Provisional application No. 63/240,224, filed on Sep. 2, 2021.

(51) Int. Cl. H01L 21/311; H01J 37/32; H01L 21/033

(52) U.S. Cl. CPC H01L 21/31144; H01J 37/3244; H01L 21/0332; H01J 37/321; H01J 2237/334

(57) ABSTRACT

A method for etching features in a carbon containing layer below a mask is provided. A simultaneous etch and passivation step is provided comprising flowing an etch gas comprising a boron containing passivant gas and an oxygen containing gas. A plasma is created from the etch gas, wherein the plasma etches features in the carbon containing layer.

### CROSS-REFERENCE TO RELATED APPLICATION

This application claims the benefit of priority of U.S. Application No. 63/240,224, filed Sep. 2, 2021, which is incorporated herein by reference for all purposes.

### BACKGROUND

The background description provided here is for the purpose of generally presenting the context of the disclosure. Information described in this background section, as well as aspects of the description that may not otherwise qualify as prior art at the time of filing, are neither expressly nor impliedly admitted as prior art against the present disclosure.

The disclosure relates to a method of forming semiconductor devices on a semiconductor wafer. More specifically, the disclosure relates to etching a carbon containing layer in the formation of semiconductor devices.

In forming semiconductor devices, holes or other features are etched. A carbon containing layer, such as an amorphous carbon layer mask may be used as a mask for etching features. In forming high aspect ratio channel features in an amorphous carbon layer mask, the etch processes have characteristics of bowing, clogging, CD, ellipticity, local CD uniformity (LCDU), and throughput. Various processes attempt to optimize these various characteristics. However, in improving one characteristic, another characteristic is sometimes made worse.

### SUMMARY

To achieve the foregoing and in accordance with the purpose of the present disclosure, a method for etching features in a carbon containing layer below a mask is provided. A simultaneous etch and passivation step is provided comprising flowing an etch gas comprising a boron containing passivant gas and an oxygen containing gas. A plasma is created from the etch gas, wherein the plasma etches features in the carbon containing layer.

In another manifestation, an apparatus for processing a wafer with a carbon containing layer is provided. A processing chamber is provided. A substrate support supports a substrate inside the processing chamber. A coil provides RF power inside the processing chamber. A gas system that simultaneously provides a boron containing passivant and oxygen into the processing chamber comprises a boron containing passivant source and an oxygen source.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1A-B are schematic cross-sectional views of a stack processed according to an embodiment.

FIGS. 2A-B are top views of the stack shown in FIGS. 1A-B.

FIG. 3 is a high level flow chart of an embodiment.

FIGS. 4A-D are cross-sectional views of stacks processed in various embodiments.

FIG. 5 is a schematic view of a semiconductor processing chamber that may be used in an embodiment.

FIG. 6 is a schematic view of a computer system that may be used in practicing an embodiment.

FIG. 7 is a schematic view of a semiconductor processing chamber that may be used in another embodiment.

### DETAILED DESCRIPTION OF THE PREFERRED EMBODIMENTS

The present embodiments will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

In the formation of semiconductor devices, a carbon containing mask may be used. In the formation of memory, such as three-dimensional not-and (3D NAND) devices and dynamic random access memory (DRAM) devices, memory stacks of alternating layers may be etched to form features. To increase chip density and reduce bit cost, 3D NAND devices keep increasing in numbers of mold stack alternating layers. The increase in the number of stack layers creates more acute challenges for pattern transfer from the lithography level down to the mold stack level. With more than 90 NAND layers, current plasma etch technology is being challenged by the continuing increase in aspect ratio etch. As the amount of memory is increased, while decreasing the size of the devices, larger numbers of alternating layers are needed and the memory stacks may become thicker. A carbon containing mask, such as amorphous carbon, may be used as a mask for etching features in memory devices. As the thickness of the stacks increases, the thickness of the carbon containing masks increase. As the thickness of the carbon containing masks increase and feature size decreases, the depth to width aspect ratios increase. In etching high aspect ratio features, the etch process may suffer from bowing and clogging. Preferably, local CD uniformity (LCDU) is minimized, while throughput is maximized and ellipticity is made closer to 1. In addition, preferably a target CD is achieved. Various processes attempt to optimize these various characteristics. However, in improving one characteristic, another characteristic is made worse.

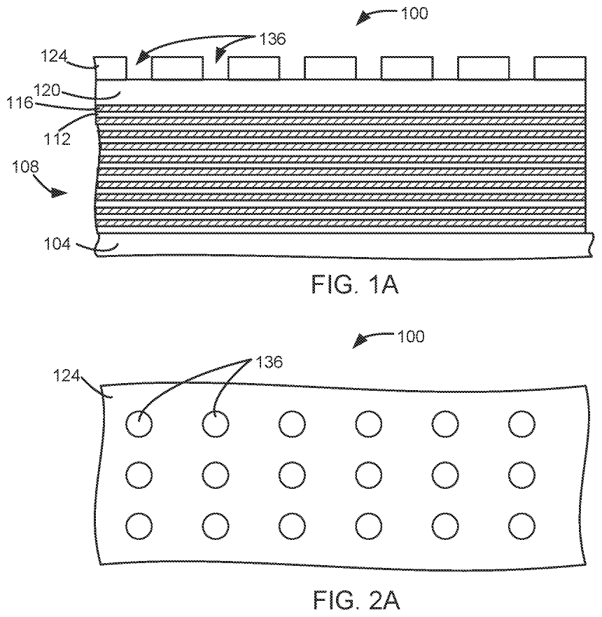

To facilitate understanding, in an embodiment, a stack comprises an ONON (silicon oxide (SiO₂), silicon nitride (SiN), silicon oxide, silicon nitride, and repeating) with a multilayer mask is provided. FIG. 1A is a schematic cross-sectional view of a stack 100 comprising a substrate 104 under a memory stack 108, comprising a plurality of bilayers of a layer of silicon oxide (SiO₂) 116 on top of a layer of silicon nitride 112. A carbon containing mask 120 is over the memory stack 108. In this embodiment, the carbon containing mask 120 comprises an amorphous carbon layer (ACL). In this embodiment, amorphous carbon is a noncrystalline carbon material. In this embodiment, a patterned mask 124 is over the carbon containing mask 120. In this embodiment, the patterned mask 124 comprises silicon oxynitride (SiON). In other embodiments, the patterned mask 124 may comprise other materials.

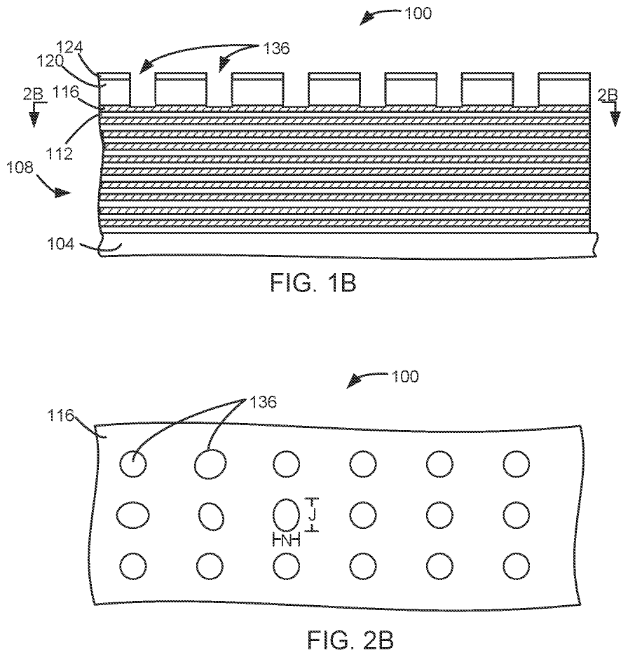

FIG. 2A is a top view of part of the stack 100, showing the top of the patterned mask 124 and the mask features 136. The mask features 136 are cylindrical holes with a circular cross-section, as shown.

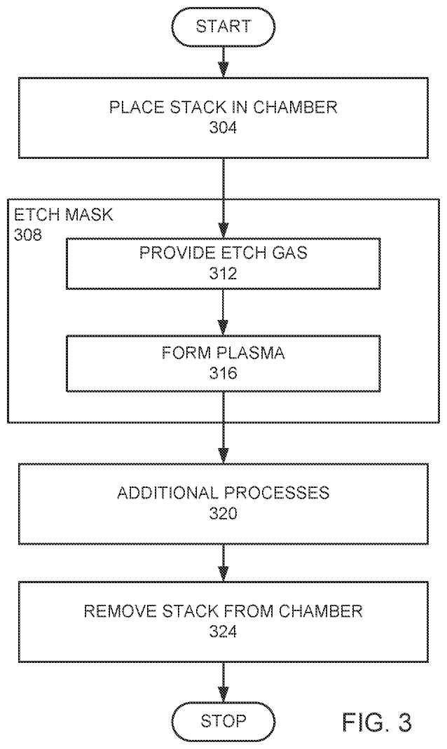

FIG. 3 is a high level flow chart of an embodiment. In this embodiment, the stack is placed in a processing chamber (step 304). The carbon containing mask 120 is opened by etching features into the carbon containing mask 120 using the patterned mask 124 (step 308). In this embodiment, the carbon containing mask 120 is etched by flowing an etch gas into the processing chamber (step 312). In this embodiment, the etch gas comprises a passivation gas and an opening gas. In this embodiment, the passivation gas comprises a boron containing gas, such as one or more of boron trichloride (BCl₃), boron trifluoride (BF₃), boron tribromide (BBr₃), BₓH_{y}, where x and y are positive integers), such as diborane (B₂H₆) or diboron dihydride (B₂H₂) and BDₓH_{y}, where D is a halogen and x and y are positive integers. In this embodiment, the opening gas comprises an oxygen containing gas, such as one or more of oxygen (O₂), sulfur dioxide (SO₂), carbonyl sulfide (COS), carbon dioxide (CO₂), and ozone (O₃). In an example, the etch gas comprises BCl₃ and SO₂.

The etch gas is formed into a plasma (step 316). In this example, the plasma is formed by providing between about 50 watts and about 10000 watts of radiofrequency (RF) power at about 13.56 MHz through A TCP coil to the processing chamber. Other embodiments may provide other RF frequencies. A pulsed bias with an amplitude of 50 volts to 3000 volts is provided to the stack 100. In this embodiment, the bias has an RF frequency of 13.56 MHz, 27 MHz, 2 MHz, 1 MHz, or 400 kHz, either in continuous wave or with a pulse frequency of between about 1 hertz (Hz) and about 10000 Hz and a duty cycle between about 3% and about 99%. After about 5 seconds to about 2000 seconds the flow of the etch gas into the processing chamber is stopped. The duration of the etching process in this embodiment is sufficient to etch features through the carbon containing mask 120. A substrate temperature of −60° C. to 120° C. is provided.

FIG. 1B is a schematic cross-sectional view of a stack 100 after the carbon containing mask 120 has been etched (step 308). FIG. 2B is a top view of part of the stack 100, showing the top of the patterned mask 124 and the mask features 136 after the carbon containing mask 120 has been etched (step 308). The etching of the carbon containing mask 120 may change the circular cross-section of the mask features 136 to be more elongated, as shown. Ellipticity is measured by an ellipticity ratio of a major axis of a feature divided by the minor axis of the feature, or sometimes vice versa. The major axis would be the widest dimension of a feature and the minor axis would be the narrowest dimension of the feature. In FIG. 2B, for one of the mask features 136 the major axis is shown as dimension J, and the minor axis is shown as dimension N. In an experiment, it was found that for the mask features 136, the ellipticity ratio was improved (closer to 1.0, which is a perfect circle) over a prior art method, without increasing the feature to feature CD variance or increasing bowing. The resulting mask would improve defect performance when the resulting carbon containing mask 120 is used to etch features in the memory stack 108. Etching the mask features 136 using a plasma formed from an etch gas comprising a boron containing passivant gas and an oxygen containing gas results in the improved ellipticity ratio without increasing the feature to feature CD variance and without increasing bowing.

The plasma sputters some of the patterned mask 124. The sputtered patterned mask 124 is redeposited and forms a silicon containing redeposited hardmask. The redeposited hardmask may change the CD and the circular cross-section of the mask features 136. The non-circular cross-section may also be caused by using a sulfur based passivation. The sulfur based passivation may deposit on the etch front in a non-uniform pattern increasing ellipticity. It has been found that adding sulfur passivation degrades ellipticity, but helps to protect CD. The sputtering and faceting of the patterned mask 124 may also cause clogging of the mask features 136 or reduction of mask feature size, bowing of the mask features 136, and degrade LCDU. Increasing temperature has been found to improve ellipticity, but increase CD. The SiON of the patterned mask 124 is nonvolatile, so that sputtered SiON will stick to parts of the features causing clogging.

It has been found that a boron containing passivation gas provides improved protection of the patterned mask 124 and sidewalls of the mask features 136 of the carbon containing mask 120. The improved protection of the patterned mask 124 reduces sputtering and redeposition of the patterned mask 124 compared to a process that uses carbon or sulfur containing passivation. The boron containing passivation has also been found to reduce clogging. In addition, it has been unexpectedly found that the boron containing passivation gas reduces bowing. The oxygen containing gas facilitates the etching of the carbon containing mask 120. In some embodiments, providing a BCl₃ passivation gas reduces clogging and patterned mask 124 consumption. As a result, bowing is also eliminated. As a result, LCDU is improved. These improvements are achieved while reducing ellipticity and without increasing CD. The use of a boron containing passivation gas allows the etch gas to be sulfur free, since the presence of a boron passivant, eliminates the need for a sulfur passivant and reduces ellipticity. In some embodiments, the etch gas is sulfur free, carbon free, and halogen free. In some embodiments, the etch gas further comprises a sulfur containing component.

Previously, two-step cyclical processes would be used to improve etch parameters. Such a two-step process may have a passivation step and an etch step. Such a cyclical process increases etch time and decreases throughput. In this embodiment, a single step is used to etch 90% to 100% of the depth of the features etched in the carbon containing mask 120. Providing a single step to etch 90% to 100% of the depth of the features decreases etch time and increases throughput. The single-step simultaneously etches and passivates in a single step.

TABLE 1

| Item | Spec | Sulfur Passivant | BCl₃ Passivant |
|---|---|---|---|
| BOW CD | <100 | 102 | 98 |
| DIMPLE CD | 55 ± 5 | 55.7 | 57.0 |
| LCDU (3s) | <3 | 2.4 | 2.4 |
| ELLIPTICITY | <1.1 | 1.09 | 1.07 |
| ETCH RATE (nm/s) | Faster is better | ~3 | >10 |

Table 1 compares the results of etching a carbon containing mask 120 using a sulfur containing passivant and the results using a BCl₃ passivant. Bow CD is the maximum CD after the mask features 136 are etched into the carbon containing mask 120. Dimple CD is the average CD after dimples are etched into the layer below the carbon containing mask 120. LCDU is the local CD uniformity, meaning 3 sigma of the whole CD. The etch rate is the average number of nanometers (nm) etched per second. Ellipticity is calculated by the major axis J divided by the minor axis N, as shown in FIG. 2B. Since the BCl₃ passivant has an ellipticity closer to 1 than using the sulfur passivant, the BCl₃ passivant provides more circular feature cross-sections. In an embodiment, the mask features 136 form channel features that have a CD in the range of 60 nm to 80 nm or contact features with a CD in the range of 150 nm to 200 nm. In other embodiments, the mask features 136 may be linear slits with widths with a CD in the range of 150 nm to 200 nm. For a hardmask opening pattern application, the CD ranges from 5 nm to 25 nm. Embodiments provide features with widths of less than 80 nm with a depth to width aspect ratio of greater than 50.

After the carbon containing mask is opened (step 308), additional process steps may be provided (step 320). In this embodiment, features are etched into the stack 108 below the carbon containing mask 120. In such a step, the carbon containing mask 120 is used as a mask for etching the stack 108 below the carbon containing mask 120 in the formation of DRAM or NAND. In various embodiments, the carbon containing mask 120 may be over other types of logic stacks and emerging memory device stacks. In some embodiments, the carbon containing mask 120 is removed after the stack 108 is etched. The stack 108 is removed from the processing chamber (step 324).

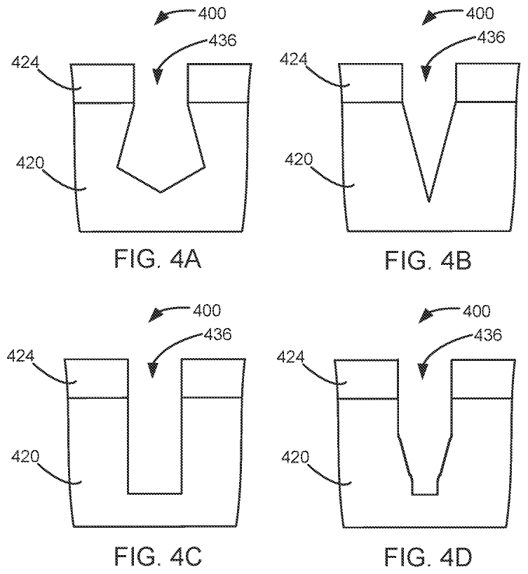

In another embodiment, the concentration of boron containing passivant may be varied or a cyclical process may be provided in order to provide profile engineering. In some embodiments, with a cyclical process or two step process with a step where the boron passivant is stopped, during that step a sulfur containing component is added. FIG. 4A is a schematic cross-sectional view of a stack 400 comprising a carbon containing mask 420 below a patterned mask 424 with slot shaped features 436. In this embodiment, the patterned mask 424 comprises silicon oxynitride (SiON) and the carbon containing mask 420 is ACL. In this example, the sidewalls of the carbon containing mask 420 are bowed. Such bow shaped features result from an etch process using an oxygen gas without a passivant gas. Since the process does not have a passivant gas, the sidewall of the carbon containing mask 420 is etched, causing the bowing shape.

FIG. 4B is a schematic cross-sectional view of a stack 400 comprising a carbon containing mask 420 below a patterned mask 424 with slot shaped features 436. In this embodiment, the patterned mask 424 comprises silicon oxynitride (SiON) and the carbon containing mask 420 is ACL. In this example, the sidewalls of the carbon containing mask 420 form a taper. Such tapered features result from an etch process using an oxygen gas and an excess of a boron containing passivant gas. The excess boron containing passivant gas protects the sidewall of the carbon containing mask 420 and results in the tapered shape.

FIG. 4C is a schematic cross-sectional view of a stack 400 comprising a carbon containing mask 420 below a patterned mask 424 with slot shaped features 436. In this embodiment, the patterned mask 424 comprises silicon oxynitride (SiON) and the carbon containing mask 420 is ACL. In this example, the sidewalls of the carbon containing mask 420 form vertical sidewalls. Such vertical sidewall result from an etch process has a tuned mixture of the oxygen gas and the boron containing passivant gas. The correct tuning of the oxygen containing gas and boron containing passivant gas protects the sidewall of the carbon containing mask 420 preventing bowing and tapering. Therefore, with proper tuning the combination of a tapering etch and a bowing results in vertical sidewalls. For features in the form of slits, the prevention of bowing is important. When the sidewalls of slits bow, the width of the slit in the middle of the features is significantly greater than the width of the slit at the top or bottom of the features. Various embodiments provide a ratio of the width of a slit in the middle of the feature to the width of a slit at the bottom of the feature of between 2:1 and 1:1.

In various embodiments, the tuning of the mixture of the oxygen containing gas and boron containing passivant may be accomplished in different ways. In the embodiment shown in FIG. 3, the oxygen containing gas and boron containing passivant are mixed together at a constant flow rate to provide a single step with a constant etch gas. As mentioned before, such a process provides a fast throughput. In another embodiment, the ratio of the oxygen containing gas and the boron containing passivation gas are changed over time. For example, the flow of the oxygen containing gas may be constant and the flow of the boron containing passivation gas is changed, such as being ramped. In another embodiment, the flow of the oxygen containing gas may be constant, while the flow of the boron containing passivation gas is pulsed. The pulsing of the boron containing passivation gas provides a temporal tuning. In another example, either or both the oxygen containing gas and boron containing passivation gas are ramped. Such ramping may be continuously increasing or continuously decreasing or may alternate between increasing and decreasing.

In other embodiments, the tuning of the mixture of the oxygen containing gas and boron containing passivant may vary over time in order to provide a specially tuned sidewall profile. FIG. 4D is a schematic cross-sectional view of a stack 400 comprising a carbon containing mask 420 below a patterned mask 424 with slot shaped features 436. In this embodiment, the patterned mask 424 comprises silicon oxynitride (SiON) and the carbon containing mask 420 is ACL. In this example, the sidewalls of the carbon containing mask 420 form upside-down bottle shaped sidewalls. In the example, the tuning provides sidewalls that are vertical near the top and bottom and tapered in the middle as shown. The vertical sidewall near the top and bottom of the features results from an etch process that has a tuned mixture of the oxygen gas and the boron containing passivant gas. This embodiment uses the bowing process and tapering process in an alternating manner to achieve the straight profile with vertical sidewalls. The bowing process and tapering process in an alternating manner may be achieved by alternating between having more boron containing passivant gas and having more oxygen gas as a function of time. The correct tuning of the oxygen containing gas and boron containing passivant gas protects the sidewall of the carbon containing mask 420 preventing bowing and tapering. The tapered sidewalls in the middle of the features result from an etch process that has an excess of boron containing passivant gas. Other embodiments may provide other tuned sidewall shapes.

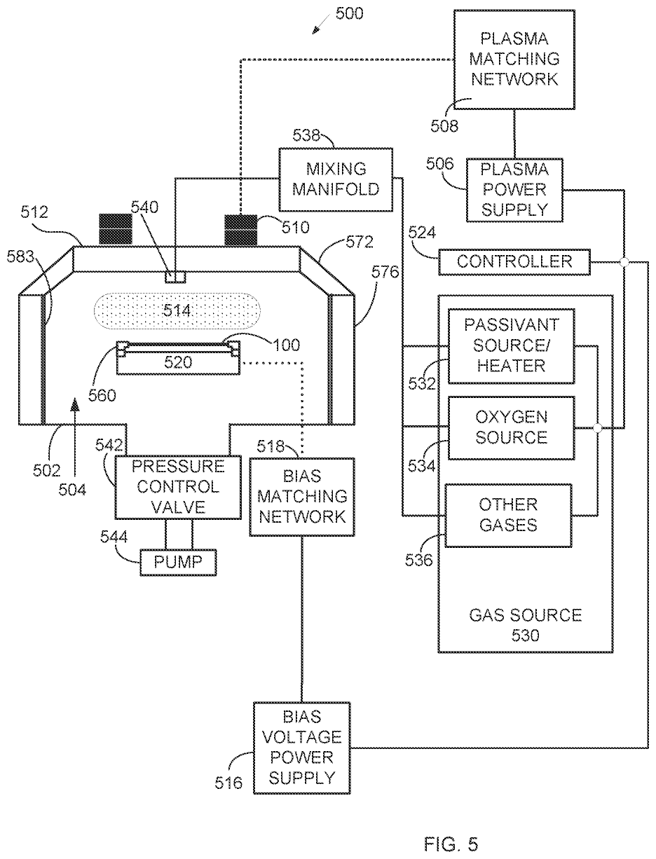

FIG. 5 schematically illustrates an example of a plasma processing system 500 which may be used to process a stack 100 in accordance with an embodiment. The plasma processing system 500 includes a plasma reactor 502 having a plasma processing chamber 504, enclosed by a chamber wall 576. A plasma power supply 506, tuned by a matching network 508, supplies power to a transformer coupled power (TCP) coil 510 located near a power window 512 to create a plasma 514 in the plasma processing chamber 504 by providing an inductively coupled power. The TCP coil (upper power source) 510 may be configured to produce a uniform diffusion profile within the plasma processing chamber 504. For example, the TCP coil 510 may be configured to generate a toroidal power distribution in the plasma 514. The power window 512 is provided to separate the TCP coil 510 from the plasma processing chamber 504 while allowing energy to pass from the TCP coil 510 to the plasma processing chamber 504. A wafer bias voltage power supply 516 tuned by a matching network 518 provides power to an electrode 520 to set the bias voltage on the stack 100 which is supported over the electrode 520. The electrode 520 is also a substrate support. A controller 524 sets points for the plasma power supply 506 and the wafer bias voltage power supply 516.

The plasma power supply 506 and the wafer bias voltage power supply 516 may be configured to operate at specific radio frequencies such as 13.56 megahertz (MHz), 27 MHz, 2 MHz, 1 MHz, 400 kilohertz (kHz), or combinations thereof. Plasma power supply 506 and wafer bias voltage power supply 516 may be appropriately sized to supply a range of powers in order to achieve desired process performance. For example, in one embodiment, the plasma power supply 506 may supply the power in a range of 50 to 10000 watts, and the wafer bias voltage power supply 516 may supply a bias voltage of in a range of 50 to 3000 volts (V). In addition, the TCP coil 510 and/or the electrode 520 may be comprised of two or more sub-coils or sub-electrodes, which may be powered by a single power supply or powered by multiple power supplies.

As shown in FIG. 5, the plasma processing system 500 further includes a gas source/gas supply mechanism 530 (gas system). The gas source/gas supply mechanism 530 provides gas to a gas feed 540 in the form of a nozzle. In this embodiment, the gas source/gas supply mechanism 530 comprises a boron containing passivant source and heater 532, oxygen source 534, and other gas sources 536. The boron containing passivant source and heater 532, oxygen source 534, and other gas sources 536 provide gas to a mixing manifold 538 that provides a plenum where the gases may be mixed before going to the gas feed 540. If the boron containing passivant is BCl₃, the heater 532 is positioned to heat and vaporize the BCl₃. In an embodiment, the controller 524 has computer readable code for simultaneously providing oxygen from the oxygen source 534 and BCl₃ from the boron containing passivant source and heater to the mixing manifold 538, where the oxygen and BCl₃ mix in the mixing manifold before flowing through the gas feed 540 into the plasma processing chamber 504. The process gases and byproducts are removed from the plasma processing chamber 504 via a pressure control valve 542 and a pump 544. The pressure control valve 542 and pump 544 may also serve to maintain a particular pressure within the plasma processing chamber 504. The gas source/gas supply mechanism 530 is controlled by the controller 524. A Kiyo by Lam Research Corp. of Fremont, CA, may be used to practice an embodiment.

In some embodiments, plasma wetted surfaces of the plasma processing system 500 have a protective coating to protect the plasma wetted surfaces from plasma generated from BCl₃ with high bias power in a range of 50 to 3000 volts. In some embodiments, the coating may further provide protection from plasma generated from a mixture of BCl₃ and oxygen with a high bias power. In some embodiments, the protective coating is at least one of a rare earth oxide, a rare earth fluoride, or a rare earth oxyfluoride. For example, the protective coating may be a coating of yttria, yttrium fluoride, or yttrium oxyfluoride. In some embodiments, the protective coating is applied using a thermal spray process. In other embodiments, other processes, such as aerosol deposition or atomic layer deposition may be used to deposit the protective coating. In some embodiments, the protective coating is provided over the electrode 520, serving as an electrostatic chuck, or on the chamber wall 576. In some embodiments, a liner is provided inside the chamber wall 576 and the protective coating is placed on plasma wetted surfaces of the liner. In FIG. 5, a protective coating 583 is shown on the plasma wetted surfaces of the chamber wall 576. In this embodiment, the chamber wall 576 is aluminum or an aluminum alloy. In this embodiment, an anodization layer is formed over a plasma facing surface of the chamber wall 576. A plasma generated from BCl₃ with a high bias would damage the anodization layer. Therefore, the protective coating 583 would protect the anodization layer in the presence of a plasma generated from BCl₃ with a high bias. In another embodiment, a ceramic plate of aluminum oxide may be placed between the electrode 520 and the stack 100. A plasma generated from BCl₃ with a high bias would damage the aluminum oxide ceramic plate. The protective coating would reduce or eliminate such damage. Damage from the plasma may create contaminants. Such contaminants would increase defects. Therefore, the protective coating would reduce defects.

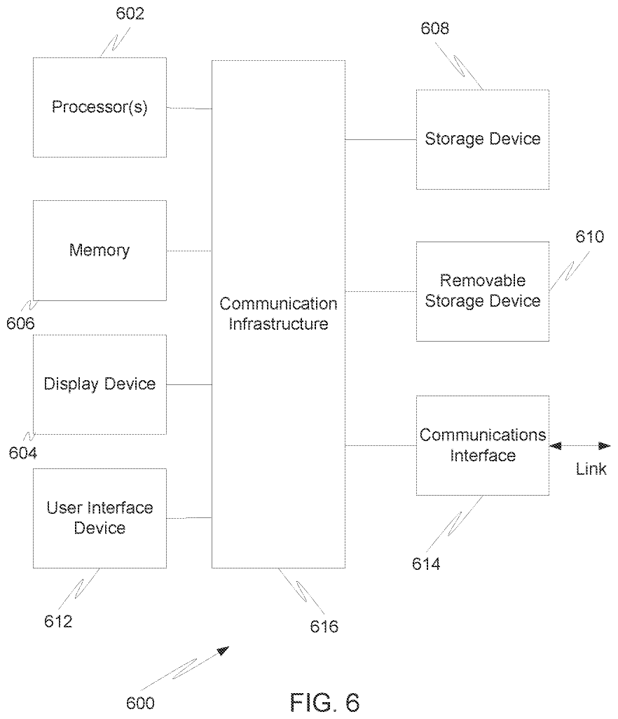

FIG. 6 is a high level block diagram showing a computer system 600, which is suitable for implementing a controller 524 used in embodiments. The computer system may have many physical forms, ranging from an integrated circuit, a printed circuit board, and a small handheld device, up to a huge super computer. The computer system 600 includes one or more processors 602, and further can include an electronic display device 604 (for displaying graphics, text, and other data), a main memory 606 (e.g., random access memory (RAM)), storage device 608 (e.g., hard disk drive), removable storage device 610 (e.g., optical disk drive), user interface devices 612 (e.g., keyboards, touch screens, keypads, mice or other pointing devices, etc.), and a communication interface 614 (e.g., wireless network interface). The communications interface 614 allows software and data to be transferred between the computer system 600 and external devices via a link. The system may also include a communications infrastructure 616 (e.g., a communications bus, cross-over bar, or network) to which the aforementioned devices/modules are connected.

Information transferred via communications interface 614 may be in the form of signals such as electronic, electromagnetic, optical, or other signals capable of being received by communications interface 614, via a communication link that carries signals and may be implemented using wire or cable, fiber optics, a phone line, a cellular phone link, a radio frequency link, and/or other communication channels. With such a communications interface, it is contemplated that the one or more processors 602 might receive information from a network, or might output information to the network in the course of performing the above-described method steps. Furthermore, method embodiments may execute solely upon the processors or may execute over a network, such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory, and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

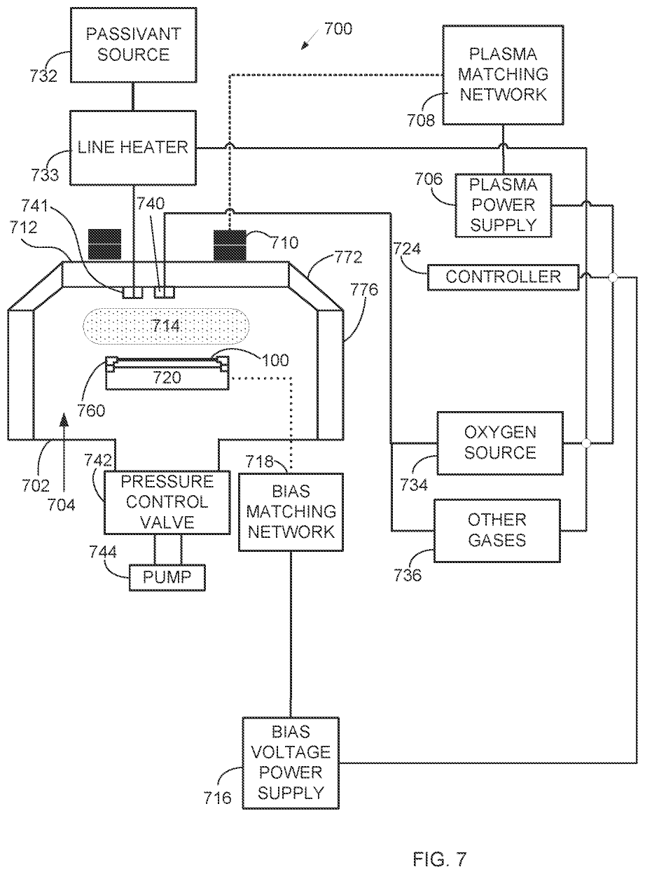

FIG. 7 schematically illustrates an example of a plasma processing system 700 which may be used to process a stack 100 in accordance with another embodiment. The plasma processing system 700 includes a plasma reactor 702 having a plasma processing chamber 704, enclosed by a chamber wall 776. A plasma power supply 706, tuned by a matching network 708, supplies power to a transformer coupled power (TCP) coil 710 located near a power window 712 to create a plasma 714 in the plasma processing chamber 704 by providing an inductively coupled power. The TCP coil (upper power source) 710 may be configured to produce a uniform diffusion profile within the plasma processing chamber 704. For example, the TCP coil 710 may be configured to generate a toroidal power distribution in the plasma 714. The power window 712 is provided to separate the TCP coil 710 from the plasma processing chamber 704 while allowing energy to pass from the TCP coil 710 to the plasma processing chamber 704. A wafer bias voltage power supply 716 tuned by a matching network 718 provides power to an electrode 720 to set the bias voltage on the stack 100 which is supported over the electrode 720. A controller 724 sets points for the plasma power supply 706 and the wafer bias voltage power supply 716.

The plasma power supply 706 and the wafer bias voltage power supply 716 may be configured to operate at specific radio frequencies such as 13.56 megahertz (MHz), 27 MHz, 2 MHz, 1 MHz, 400 kilohertz (kHz), or combinations thereof. Plasma power supply 706 and wafer bias voltage power supply 716 may be appropriately sized to supply a range of powers in order to achieve desired process performance. For example, in one embodiment, the plasma power supply 706 may supply the power in a range of 50 to 5000 watts, and the wafer bias voltage power supply 716 may supply a bias voltage of in a range of 0 to 3000 volts (V). In addition, the TCP coil 710 and/or the electrode 720 may be comprised of two or more sub-coils or sub-electrodes, which may be powered by a single power supply or powered by multiple power supplies.

As shown in FIG. 7, the plasma processing system 700 further includes a gas source/gas supply mechanism comprising a boron containing passivant source 732, an oxygen source 734, and other gas sources 736. The oxygen source 734 and other gas sources 736 provide gas to a first gas feed 740. If the boron containing passivant is BCl₃ a line heater 733 is provided to heat the line to vaporize the BCl₃. In this embodiment, the boron containing passivant source 732 is connected through the line heater 733 to a second gas feed 741. In this embodiment, the controller 724 comprises computer readable code for simultaneously flowing oxygen from the oxygen source 734 and boron containing passivant from the boron containing passivant source 732 to be mixed in the plasma processing chamber 704. The process gases and byproducts are removed from the plasma processing chamber 704 via a pressure control valve 742 and a pump 744. The pressure control valve 742 and pump 744 may also serve to maintain a particular pressure within the plasma processing chamber 704. The gas source/gas supply mechanism 730 is controlled by the controller 724. The position of the first gas feed 740 and the second gas feed 741 may be placed in various positions depending on desired gas distribution and mixing.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for etching features in a carbon containing layer below a mask, comprising:
a simultaneous etch and passivation step, comprising:
flowing an etch gas comprising a boron containing passivant gas and an oxygen containing gas; and
creating a plasma from the etch gas, wherein the plasma etches features in the carbon containing layer.

2. The method, as recited in claim 1, wherein the boron containing passivant gas is at least one of BCl₃, (BF₃), BBr₃, BₓH_{y}, where x and y are positive integers, and BDₓH_{y}, where D is a halogen and x and y are positive integers.

3. The method, as recited in claim 1, wherein the features have a CD of less than 80 nm and an aspect ratio of greater than 50.

4. The method, as recited in claim 1, further comprising etching a stack below the carbon containing layer, wherein the carbon containing layer acts as a mask.

5. The method as recited in claim 4, wherein the stack is a 3D NAND stack or DRAM stack or other logic stacks or memory stack.

6. The method, as recited in claim 1, further comprising an etch without a passivation gas, comprising:
flowing an etch gas without a passivation gas comprising an oxygen containing gas, wherein the etch without passivation is boron free; and
creating a plasma from the etch gas without a passivation gas.

7. The method, as recited in claim 6, wherein the flowing the etch gas without a passivation gas comprises flowing the etch gas with a sulfur containing component.

8. The method, as recited in claim 1, wherein the etch gas is sulfur free.

9. The method, as recited in claim 1, wherein the etch gas is halogen free.

10. The method, as recited in claim 1, wherein the carbon containing layer comprises amorphous carbon.

11. The method, as recited in claim 10, wherein the mask comprises SiON.

12. The method, as recited in claim 1, wherein the features form slits with a width CD in a range of 150 nm to 200 nm.

13. The method, as recited in claim 1, wherein the boron containing passivant and oxygen containing gas are mixed before being flowed into a processing chamber.

14. The method, as recited in claim 1, wherein the boron containing passivant and oxygen containing gas are mixed in a processing chamber before creating the plasma from the etch gas.

15. The method, as recited in claim 1, wherein the features have a CD in a range of 150 nm to 200 nm.

16. An apparatus for processing a wafer with a carbon containing layer, comprising:
a processing chamber;
a substrate support for supporting a substrate inside the processing chamber;
a coil for providing RF power inside the processing chamber; and
a gas system that simultaneously provides a boron containing passivant and oxygen into the processing chamber, comprising:
a boron containing passivant source; and
an oxygen source.

17. The apparatus, as recited in claim 16, wherein the gas system further comprises a plenum connected to the boron containing passivant source and the oxygen source, wherein the boron containing passivant and the oxygen mix in the plenum before entering the processing chamber.

18. The apparatus, as recited in claim 16, wherein the gas system further comprises controller controllably connected to the boron containing passivant source and the oxygen source, wherein the controller comprises computer readable code for simultaneously flowing the boron containing passivant and the oxygen into the processing chamber.

19. The apparatus, as recited in claim 16, further comprising a heater positioned to heat boron containing passivant from the boron containing passivant source.

20. The apparatus, as recited in claim 16, wherein the processing chamber comprises a protective coating comprising at least one a rare earth oxide, a rare earth fluoride, or a rare earth oxyfluoride.
